(19) United States
(12) Patent Application Publication
(10) Pub. No.: US 2025/0306108 A1
(43) Pub. Date: Oct. 2, 2025

(54) BATTERY SYSTEM

(71) Applicant: TOYOTA JIDOSHA KABUSHIKI KAISHA, Toyota-shi (JP)

(72) Inventor: Yuki SUGO, Seto-shi (JP)

(73) Assignee: TOYOTA JIDOSHA KABUSHIKI KAISHA, Toyota-shi (JP)

(21) Appl. No.: 19/063,637

(22) Filed: Feb. 26, 2025

(30) Foreign Application Priority Data
Mar. 29, 2024 (JP) 2024-056740

(51) Int. Cl. G01R 31/36; G01R 31/367; G01R 31/371; G01R 31/3828; G01R 31/392

(52) U.S. Cl. CPC G01R 31/3646; G01R 31/367; G01R 31/371; G01R 31/3828; G01R 31/392

(57) ABSTRACT

A controller performs the steps of: acquiring a charge/discharge history, when a display update condition is satisfied; estimating a degree of degradation of a battery; acquiring a threshold value of segment display; when it is determined that the degree of degradation is smaller than the threshold value and a predetermined time has elapsed, updating segment display; and updating numerical value display.

### CROSS REFERENCE TO RELATED APPLICATIONS

This nonprovisional application is based on Japanese Patent Application No. 2024-056740 filed on Mar. 29, 2024 with the Japan Patent Office, the entire contents of which are hereby incorporated by reference.

### BACKGROUND

### Field

The present disclosure relates to a battery system.

### Description of the Background Art

In WO2020/234982, there is disclosed a technique of, after an operation is performed on an execution switch to display calibration information of a battery, controlling a display unit to perform display based on a ratio of a full charge capacity of the battery at that time point to a full charge capacity at the time point when the operation is performed.

### SUMMARY

However, for example, when the degree of degradation of the secondary battery such as a battery is calculated using the full charge capacity of the secondary battery and the calculated degree of degradation is displayed, a user may feel strange due to a change in the degree of degradation displayed in a period in which the amount of change in the initial full charge capacity of the secondary battery is large.

An object of the present disclosure is to provide a battery system that does not give a feeling of strangeness about a change in display of the degree of degradation of a secondary battery.

A battery system according to an aspect of the present disclosure includes: a secondary battery mounted on a vehicle; a controller that calculates a degree of degradation of the secondary battery; and a display that displays the degree of degradation indicated by a numerical value and the number of segments. The controller causes the display to display the segments, the number of the segments being set in accordance with weighting applied depending on the degree of degradation.

Thus, the segments of the number that is set in accordance with the weighting applied depending on the degree of degradation are displayed, and therefore, for example, by setting the weighting in such a manner that the change in the number of segments is gentler in a period in which the degree of degradation sharply changes, it is possible to prevent the user from feeling strange about the change in the degree of degradation.

In an embodiment, the weighting is set in such a manner that the secondary battery in an initial state and the secondary battery in a non-initial state are identical to each other in terms of a timing at which the number of segments is changed.

Thus, the initial state and the non-initial state are identical to each other in terms of the timing at which the number of segments is changed, and therefore, it is possible to prevent the user from feeling strange about the change in the degree of degradation in the period in which the degree of degradation sharply changes.

Further, in an embodiment, the controller changes the number of displayed segments based on a predetermined period or a predetermined degree of degradation.

Thus, the number of displayed segments is changed based on a predetermined period or a predetermined degree of degradation, and therefore, it is possible to prevent the user from feeling strange about the change in the degree of degradation in a period in which the degree of degradation sharply changes.

The foregoing and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a diagram showing an example of a configuration of a vehicle equipped with a battery system.

FIG. 2 is a flowchart showing an example of processing executed by a controller.

FIG. 3 is a diagram illustrating an example of a display screen displayed on a display.

### DESCRIPTION OF THE PREFERRED EMBODIMENTS

Hereinafter, embodiments of the present disclosure will be described in detail with reference to the drawings. In the drawings, the same or corresponding parts are denoted by the same reference numerals, and the description thereof will not be repeated.

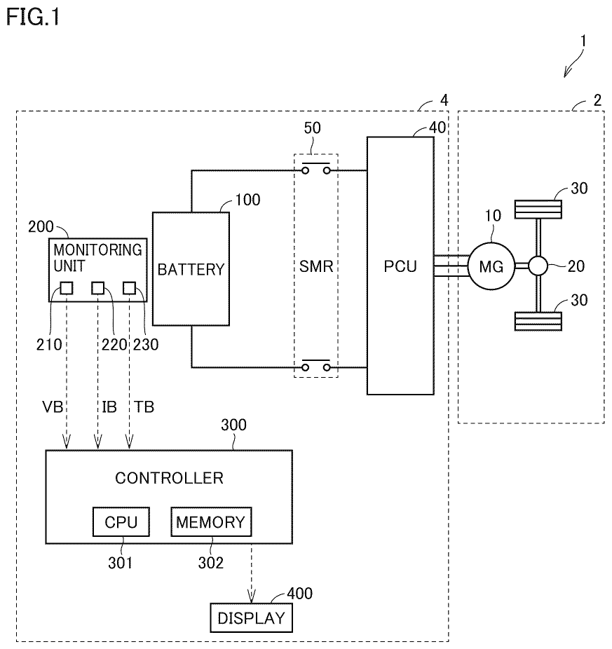

Hereinafter, a configuration of a vehicle on which the battery system according to the present embodiment is mounted will be described. FIG. 1 is a diagram illustrating an example of a configuration of a vehicle 1 on which a battery system 4 is mounted.

In the present embodiment, a case where the vehicle 1 is, for example, a battery electric vehicle will be described as an example, but the vehicle 1 may be any electrically powered vehicle and may be, for example, a hybrid electric vehicle. As shown in FIG. 1, the vehicle 1 includes a drive system 2 and a battery system 4.

The drive system 2 includes an electrical load of the battery system 4. Specifically, the drive system 2 includes a motor generator (MG) 10, a power transmission gear 20, and drive wheels 30.

The MG 10 is, for example, a three-phase AC rotating electrical machine, and has a function as an electric motor (motor) and a function as a generator (generator). The output torque of the MG 10 is transmitted to the drive wheels 30 via a power transmission gear 20 including a speed reducer, a differential gear, and the like.

During braking of the vehicle 1, the MG 10 is driven by the drive wheels 30, and the MG 10 operates as a generator. Thus, the MG 10 also functions as a braking device that performs regenerative braking to convert kinetic energy of the vehicle 1 into electric power. The regenerative electric power generated by the regenerative braking force in the MG 10 is supplied to the battery system 4.

The battery system 4 includes a power control unit (PCU) 40, a system main relay (SMR) 50, a battery (secondary battery) 100, a monitoring unit 200, a controller 300, and a display 400.

The PCU 40 is a power conversion device that bidirectionally converts power between the MG 10 and the battery 100. The PCU 40 includes, for example, an inverter and a converter.

The converter boosts the voltage supplied from the battery 100 when the battery 100 is discharged, and supplies the boosted voltage to the inverter. The inverter converts DC power supplied from the converter into AC power to drive the MG 10.

On the other hand, when the battery 100 is charged, the inverter converts AC power (regenerative power) generated by the MG 10 into DC power and supplies the DC power to the converter. The converter steps down the voltage supplied from the inverter to a voltage suitable for charging the battery 100, and supplies the voltage to the battery 100.

The PCU 40 stops charging and discharging by stopping the operation of the inverter and the converter. The PCU 40 may have a configuration in which the converter is omitted.

The SMR 50 is electrically connected to a power line connecting the battery 100 and the PCU 40. When the SMR 50 is closed (i.e., in a conductive state), power can be exchanged between the battery 100 and the PCU 40. On the other hand, when the SMR 50 is open (i.e., in the cut-off state), the electrical connection between the battery 100 and the PCU 40 is cut off.

The battery 100 is a power storage device that stores electric power for driving the MG 10. The battery 100 is a rechargeable DC power supply, and is configured by, for example, connecting a plurality of cells in series. The cell includes, for example, a secondary battery such as a nickel-metal hydride battery or a lithium ion battery. The battery 100 may be configured by, for example, connecting a plurality of parallel battery blocks configured by connecting a plurality of cells in parallel in series.

The monitoring unit 200 is provided in the battery 100. The monitoring unit 200 includes a voltage detection unit 210, a current detection unit 220, and a temperature detection unit 230. The voltage detection unit 210 detects the voltage VB between the terminals of the battery 100. The current detection unit 220 detects a current IB input to and output from the battery 100. The temperature detection unit 230 detects the temperature TB of the battery 100. Each detection unit outputs the detection result to the controller 300. For example, the monitoring unit 200 may store information indicating a history of various detection results in a memory (not shown) and output the information stored in the memory to the controller 300 every time a predetermined time elapses.

The controller 300 includes CPU (Central Processing Unit) 301 and a memory 302. The memory 302 includes, for example, a read only memory (ROM), a random access memory (RAM), and the like. The controller 300 controls the display 400 based on a signal received from the monitoring unit 200, and information such as a map and a program stored in the memory 302. Various kinds of control performed by the controller 300 are not limited to processing by software, and processing can also be performed by dedicated hardware (electronic circuit). The controller 300 is configured by, for example, an ECU (Electronic Control Unit).

The controller 300 stores the detection value from the monitoring unit 200 in the memory 302. The controller 300 has a function of sequentially calculating an SOC (State Of Charge) of the battery 100 based on the detection values of the voltage detection unit 210, the current detection unit 220, and the temperature detection unit 230. The SOC indicates the current amount of power stored in the battery 100 by a percentage of 100 parts. As a method of calculating the SOC, for example, various known methods such as a method based on current value integration (coulomb count) or a method based on estimation of an open circuit voltage (OCV) can be adopted.

The display 400 has a screen configured by a display unit such as an LCD (Liquid Crystal Display) liquid crystal display or an organic EL (Electro-Luminescence) display. Predetermined information is displayed on the display unit of the display 400 in accordance with a control signal from the controller 300. In the present embodiment, display 400 includes, for example, at least one of a display provided at a position (for example, in front of the front seat) visible to the driver seated in the room of vehicle 1 and a display of a mobile terminal such as a smartphone carried by the user.

Further, the controller 300 estimates the degree of degradation of the battery 100. In the present embodiment, as an example, for example, a “full charge capacity retention” defined by the percentage of the current full charge capacity with respect to the full charge capacity (Ah) at the time the battery is new is calculated as the degree of degradation of the battery 100, and the degree of progress of degradation is quantitatively evaluated. The higher the full charge capacity retention, the lower the degree of degradation of the battery 100 and, the lower the full charge capacity retention, the higher the degree of degradation of the battery 100.

For example, when a predetermined time has elapsed from the execution timing of the display control for displaying the degree of degradation last time and the degree of degradation is updated, the controller 300 estimates the current value of the full charge capacity of the battery 100 by using the change amount of the SOC and the integrated value of the charge/discharge current in the period up to that time. The controller 300 may calculate, as the estimated value of the degree of degradation, a full charge capacity retention calculated from the current value of the estimated full charge capacity and the full charge capacity at the time the battery is new.

Alternatively, for example, the controller 300 may set a plurality of use regions divided by the temperature and the SOC of the battery 100, obtain a frequency distribution used in each use region in a period from the execution of the display control of the degree of degradation last time to the elapse of a predetermined time, calculate the degree of degradation progress in each region from the obtained frequency distribution, and calculate the estimated value of the degree of degradation using the decrease amount of the full charge capacity retention calculated from the degree of degradation progress and the use time in each region. The method of estimating the degree of degradation of the battery 100 is not limited to the above-described method, and a known technique may be applied.

The controller 300 causes the display 400 to display information about the estimated degree of degradation. More specifically, the controller 300 causes the display 400 to display the degree of degradation based on the numerical value and the number of segments.

The controller 300 displays, for example, a numerical value of the current full charge capacity retention as the degree of degradation. Further, the controller 300 sets the number of segments corresponding to the current full charge capacity retention to the display state in the first mode. The segment is configured by, for example, a rectangular shape. The segment is constituted by a rectangular image displayed in the screen. In the present embodiment, controller 300 displays the current degree of degradation using, for example, ten segments. For example, in the initial state in which the battery 100 is not degraded, the controller 300 sets each of the ten segments to the display state in the first mode. The controller 300 decreases the number of segments that are in the display state in the first mode as the degradation of the battery 100 progresses. For example, the controller 300 reduces the number of segments in the display state in the first mode by changing the segments in the display state in the first mode (for example, the hatched region) to the display state in the second mode (the white region).

However, when the calculated degree of degradation is displayed, if the displayed degree of degradation sharply changes in a period in which the change amount of the full charge capacity in the initial stage of use of the battery 100 is relatively large, the user may feel strange.

Therefore, in the present embodiment, it is assumed that the controller 300 causes the display 400 to display the degree of degradation by the numerical value and the number of segments, and causes the display 400 to display the number of segments set in accordance with the weighting applied depending on the degree of degradation. The weighting is set in such a manner that the secondary battery in the initial state and the secondary battery in non-initial state are identical to each other in terms of the timing at which the number of segments is changed.

In this way, since the number of segments set in accordance with the weighting applied depending on the degree of degradation is displayed, for example, by setting the weighting in such a manner that the change in the number of segments is gentler in the period in which the degree of degradation sharply changes, it is possible to prevent the user from feeling strange about the change in the degree of degradation.

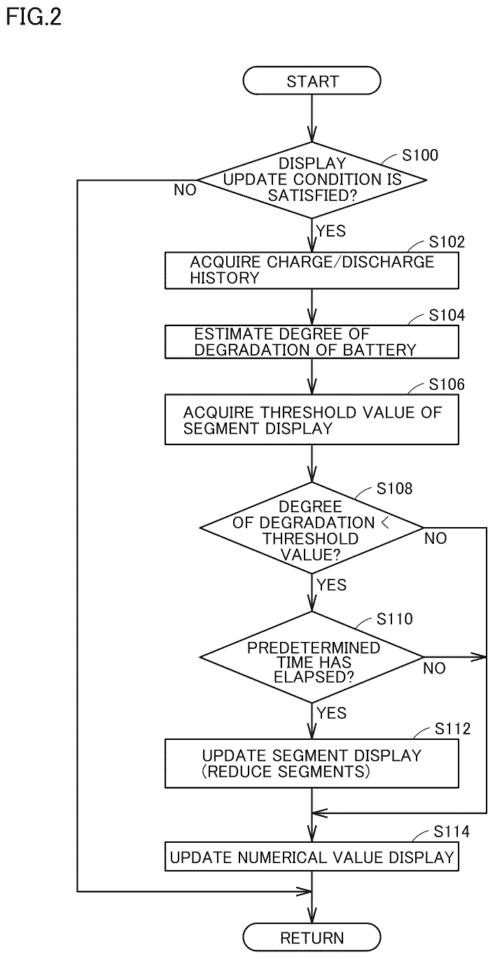

Hereinafter, an example of processing executed by the ECU 100 will be described with reference to FIG. 2. FIG. 2 is a flowchart illustrating an example of processing executed by the ECU 100.

In step S100, the controller 300 determines whether a display update condition is satisfied. The display update condition may include, for example, a condition that a predetermined period of time has elapsed from the execution timing of the display control for displaying the information about the degree of degradation last time, or may include a condition that the latest degree of degradation is requested to be displayed by accepting an operation of the user. When it is determined that the display update condition is satisfied (YES in S100), the process proceeds to S102.

In S102, controller 300 acquires a charge/discharge history. For example, the controller 300 may acquire information corresponding to the charge/discharge history from the memory 302, or may acquire information corresponding to the charge/discharge history from the monitoring unit 200. The charge/discharge history includes information used to estimate the degree of degradation. The charge/discharge history includes, for example, history information of the temperature, the current, and the voltage of the battery 100 in a predetermined period. Thereafter, the process proceeds to S104.

In S104, controller 300 estimates the degree of degradation of battery 100. Since the method of calculating the estimated value of the degree of degradation of the battery 100 is as described above, the detailed description thereof will not be repeated. Thereafter, the process proceeds to S106.

In step S106, the controller 300 acquires the threshold value of the segment display. The threshold value is a threshold value of the degree of degradation that changes the number of segments in the display state in the first mode. In the present embodiment, a plurality of segments are composed of 10 rectangular segments. For example, ten segments are arranged along the horizontal direction. In the case of no degradation (initial state), the controller 300 sets 10 segments in the display state in the first mode. The first mode includes, for example, a lighting state or a state indicating a region of a predetermined color.

When the degree of degradation progresses, the controller 300 decreases the number of segments to be displayed in the first mode and displays the segments. The controller 300 sets all the segments to the display state in the first mode from the non-degradation state (state in which the degree of degradation (capacity retention) is 100%) until the degree of degradation reaches the first threshold value. Until the degree of degradation becomes the second threshold value from the first threshold value, the controller 300 sets only the segments disposed at one of the left and right ends (the right end in the present embodiment) to the display state in the second mode, and sets the other nine segments to the display state in the first mode. The second aspect includes, for example, a light-off state or a state indicating a region of a color different from the above-described predetermined color.

The controller 300 sets the two segments on the right side in the display state in the second mode and sets the other eight segments in the display state in the first mode until the degree of degradation becomes the third threshold value from the second threshold value. The controller 300 sets the three segments on the right side in the display state in the second mode and sets the other seven segments in the display state in the first mode until the degree of degradation becomes the fourth threshold value from the third threshold value. The controller 300 sets the four segments on the right side in the display state in the second mode and sets the other six segments in the display state in the first mode until the degree of degradation becomes the fifth threshold value from the fourth threshold value. The controller 300 sets the five segments on the right side to the display state in the second mode and sets the other five segments to the display state in the first mode until the degree of degradation becomes the sixth threshold value from the fifth threshold value. The controller 300 sets the six segments on the right side in the display state in the second mode and sets the other four segments in the display state in the first mode until the degree of degradation becomes the seventh threshold value from the sixth threshold value. During the period from the seventh threshold value to the eighth threshold value, the controller 300 sets the seven segments on the right side to the display state in the second mode, and sets the other three segments to the display state in the first mode. The controller 300 sets the eight segments on the right side in the display state in the second mode and sets the other two segments in the display state in the first mode until the degree of degradation becomes the ninth threshold value from the eighth threshold value. When the degree of degradation is lower than the ninth threshold value, the controller 300 sets the nine segments on the right side to the display state in the second mode, and sets the other one segment to the display state in the first mode.

The controller 300 acquires the threshold value according to the number of segments in the current display state in the first mode. For example, when 10 segments are in the display state in the first mode, the controller 300 sets the first threshold value as the threshold value. Similarly, for example, the controller 300 acquires the second threshold value as the threshold value when nine segments are in the display state in the first mode, and acquires the third threshold value as the threshold value when eight segments are in the display state in the second mode. In this way, the first threshold value to the ninth threshold value correspond to the number of segments in the display state of the first mode, and the controller 300 sets the threshold value using the number of segments in the display state of the first mode.

The first to ninth threshold values are stored in the memory 302 of the controller 300 as predetermined values. The first to ninth threshold values are set in advance in accordance with weighting according to the degree of degradation. The weighting is set so that the timing at which the number of segments in the display state in the first mode changes is the same between the case where the battery 100 is in the initial state and the case where it is not in the initial state.

In the present embodiment, for example, it is assumed that the first threshold value is set to 80%, the second threshold value is set to 70%, the third threshold value is set to 60%, the fourth threshold value is set to 50%, the fifth threshold value is set to 40%, the sixth threshold value is set to 30%, the seventh threshold value is set to 20%, the eighth threshold value is set to 10%, and the ninth threshold value is set to 5%. Thereafter, the process proceeds to S108.

In S108, controller 300 determines whether the degree of degradation is smaller than a threshold value. Since the threshold is as described above, detailed description thereof will not be repeated. When it is determined that the degree of degradation is smaller than the threshold value (YES in S108), the process proceeds to S110.

In S110, controller 300 determines whether a predetermined time has elapsed. When the duration (elapsed time from the point in time when the number of segments in the most recent display state of the first aspect has changed) of the display state of the current segment exceeds the predetermined time, the controller 300 determines that the predetermined time has elapsed. When it is determined that the predetermined time has elapsed (YES in S110), the process proceeds to S112.

In S112, controller 300 updates the segment display. More specifically, the controller 300 reduces the number of segments in the display state in the first mode. Thereafter, the process proceeds to S112. When it is determined that the predetermined time has not elapsed (NO in S110), the process proceeds to S114. When it is determined that the degree of degradation is equal to or greater than the threshold value (NO in S108), the process proceeds to S114.

In S114, controller 300 updates the numerical value display of the degree of degradation to a numerical value corresponding to the estimated degree of degradation. Thereafter, the process ends.

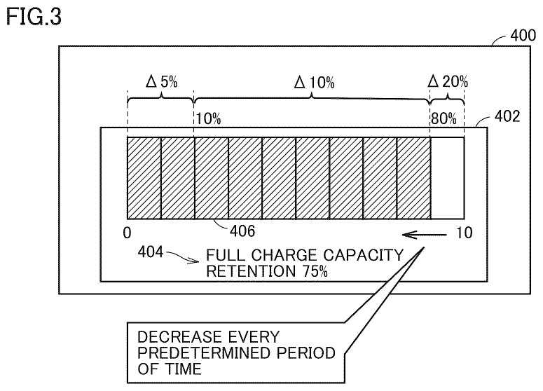

An example of the operation of the controller 300 based on the above-described structure and flowchart will be described with reference to FIG. 3. FIG. 3 is a diagram illustrating an example of a display screen displayed on the display 400. As illustrated in FIG. 3, the display 400 includes a display unit 402 having a display screen. Above the display unit 402, ten rectangular segments 406 are arranged in contact with adjacent segments. Below the display unit 402, the full charge capacity retention is displayed as the degree of degradation. FIG. 3 shows an example in which the number of segments in the display state of the first mode (hatched area in FIG. 3) among the ten segments is nine, and the number of segments in the display state of the second mode (open area in FIG. 3) is one. Further, FIG. 3 shows an example in which the full charge capacity retention of 75% is displayed as a numerical value.

For example, when the vehicle 1 is used in a non-degraded state, every time the display update condition is satisfied (YES in S100), the charge/discharge history is acquired (S102), and the degree of degradation of the battery 100 is estimated (S104). Then, a threshold corresponding to the current segment display number is acquired (S106).

For example, as shown in FIG. 3, when nine segments among ten segments are in the display state in the first mode, the second threshold value (70%) is acquired as the threshold value.

When the estimated degree of degradation (full charge capacity retention) is 75%, since the degree of degradation is equal to or greater than the threshold value (70%) (NO in S108), only the numerical value is updated to 75%.

In a case where nine segments among the ten segments are in the display state in the first mode, when degradation of the battery 100 progresses and the degree of degradation reaches 68%, it is determined that the degree of degradation is smaller than the threshold value (70%) (YES in S108). At this time, when a predetermined period has elapsed from the point in time when the nine segments are in the display state in the first mode (YES in S110), the segment display is updated, eight segments among the ten segments are in the display state in the first mode, and the two segments on the right side are in the display state in the second mode.

As described above, since the number of segments in the display state of the first mode decreases at the timing when the predetermined period elapses with respect to the progress of the degradation of the battery 100, even if the degree of degradation suddenly changes when the battery 100 is in the initial state, the sudden change in the number of segments in the display state of the first mode is suppressed. As a result, it is possible to prevent the user from feeling strange about a change in the display of the segment.

As described above, according to the battery system 4 of the present embodiment, the segment is displayed in the display state of the first state based on the threshold value set according to the weighting according to the degree of degradation of the battery 100. In particular, by setting the weighting so that the change in the number of segments becomes gentle in the period (initial state) in which the degree of degradation suddenly changes (The first threshold value and the second threshold value are set such that the magnitude from 100% to the first threshold value is greater than the magnitude from the first threshold value to the second threshold value.), it is possible to suppress the user from feeling strange about the change in the degree of degradation. Therefore, it is possible to provide a battery system that does not give a feeling of strangeness to a change in the display of the degree of degradation of the secondary battery.

Further, the weighting is set so that the timings at which the number of segments changes are the same between the case where the battery 100 is in the initial state and the case where it is not in the initial state. Therefore, it is possible to prevent the user from feeling strange about the change in the degree of degradation in the period in which the degree of degradation suddenly changes.

Further, since the number of segments to be displayed changes based on the predetermined period, it is possible to suppress the user from feeling strange about the change in the degree of degradation in the period in which the degree of degradation suddenly changes.

Hereinafter, modifications will be described.

In the above-described embodiment, the number of segments in the display state of the first aspect is reduced when the degree of degradation becomes smaller than the threshold value and a predetermined time elapses regardless of the number of segments in the display state of the first aspect, but the threshold value for determining the elapsed time may be changed according to the number of segments in the display state of the first aspect.

Further, in the above-described embodiment, the case where the plurality of segments is constituted by 10 segments has been described as an example, but the number of segments is not limited to 10.

Further, in the above-described embodiment, a case where the segment has a rectangular shape has been described as an example, but the segment may have a predetermined shape, or a plurality of segments may have different shapes. Further, the segments may have one shape as a whole (for example, a circular shape), and may have a shape corresponding to the element into which each segment is divided (for example, a fan shape).

Further, in the above-described embodiment, the case where the plurality of segments are arranged in one row in the horizontal direction has been described as an example, but the plurality of segments may be arranged in two or more rows in the arrangement direction, or may be arranged in one or more rows in the vertical direction.

Further, in the above-described embodiment, the number of segments to be displayed is changed based on a predetermined period, but the number of segments to be displayed may be changed based on a predetermined degree of degradation in addition to or instead of the predetermined period. In this case, for example, the range of the degree of degradation in which 10 segments are displayed in the first mode may be set to be larger than the range of the degree of degradation in which the other number (for example, 9 or less) of segments are displayed in the first mode. In this way, it is possible to prevent the user from feeling strange about the change in the degree of degradation in the period in which the degree of degradation suddenly changes.

All or a part of the above-described modified examples may be appropriately combined.

Although the present disclosure has been described and illustrated in detail, it is clearly understood that the same is by way of illustration and example only and is not to be taken by way of limitation, the scope of the present disclosure being interpreted by the terms of the appended claims.

What is claimed is:

1. A battery system comprising:
a secondary battery mounted on a vehicle;
a controller that calculates a degree of degradation of the secondary battery; and
a display that displays the degree of degradation indicated by a numerical value and the number of segments, wherein
the controller causes the display to display the segments, the number of the segments being set in accordance with weighting applied depending on the degree of degradation.

2. The battery system according to claim 1, wherein the weighting is set in such a manner that the secondary battery in an initial state and the secondary battery in a non-initial state are identical to each other in terms of a timing at which the number of segments is changed.

3. The battery system according to claim 1, wherein the controller changes the number of displayed segments based on a predetermined period or a predetermined degree of degradation.
